(19) United States
(12) Patent Application Publication
(10) Pub. No.: US 2024/0111155 A1
(43) Pub. Date: Apr. 4, 2024

(54) EFFICIENT HEAT-DISSIPATING HEAD UP DISPLAY

(71) Applicant: Shenzhen Raythink Technology Co., Ltd., Shenzhen (CN)

(72) Inventors: Zhenying Hu, Shenzhen (CN); Rui Lu, Shenzhen (CN); Shuguang Huang, Shenzhen (CN); Yingjun Wang, Shenzhen (CN)

(21) Appl. No.: 18/373,979

(22) Filed: Sep. 28, 2023

(30) Foreign Application Priority Data
Sep. 29, 2022 (CN) 202211201392.9

(51) Int. Cl. G02B 27/01; H05K 7/20

(52) U.S. Cl. CPC G02B 27/0149; G02B 27/0101; H05K 7/20963; G02B 2027/0154

(57) ABSTRACT

Disclosed in the present invention is an efficient heat-dissipating head-up display (HUD), including an outer housing, on which a light outlet through-hole is provided; a light source housing, wherein the light source housing and the outer housing are detachably connected, and an optical machine mechanism is also installed in the light source housing, and the optical machine mechanism is used to output image light to the outer housing; and a heat conducting member is also connected between the optical machine mechanism and the light source housing, and the heat conducting member is used to conduct heat generated by the optical machine mechanism to the light source housing. In the present invention, the heat generated by the optical machine mechanism in the operating process can be directly conducted to the light source housing through the heat conducting member, thus improving the heat conduction efficiency.

### CROSS REFERENCE TO RELATED APPLICATIONS

The present application claims the benefit of Chinese Patent Application No. 202211201392.9 filed on Sep. 29, 2022, the contents of which are incorporated herein by reference in their entirety.

### FIELD OF TECHNOLOGY

The present invention relates to the technical field of head up display (HUD), in particular to an efficient heat-dissipating HUD.

### BACKGROUND TECHNOLOGY

A head-up display, also known as Head Up Display (abbreviated as HUD), which is commonly used in flight auxiliary instruments of aircrafts, and now has gradually become popular in vehicles. The HUD aims to make vehicles safer and keep drivers focused on roads to reduce accidents. In recent years, with a rapid development of an HUD market, more and more vehicle models began to be mounted with HUD products.

The HUD products are divided into Initial assembly HUDs and Optional assembly HUDs, wherein each Initial assembly HUD generally needs to be installed inside an instrument panel of a vehicle, and forms one of imaging elements through a front windshield of the vehicle so as to form a projected virtual image. At present, the on-board HUD usually uses an optical machine (digital optical processing optical machine) as an image source, but a structure design of the existing optical machine is too complicated, resulting in inconvenient HUD installation and maintenance, and overall HUD heat-dissipating effect is not good, so it needs to be improved.

### SUMMARY OF THE INVENTION

The present invention aims to provide an efficient heat-dissipating head up display (HUD).

By connecting a heat conducting member between an optical machine mechanism and a light source housing, heat generated by the optical machine mechanism in an operating process can be directly conducted to the light source housing through the heat conducting member, thus improving the heat conduction efficiency. Then, the first heat-dissipating member arranged on the light source housing would directly dissipate the heat conducted by the heat conducting member to the outside, which greatly improves heat dissipation effect of the optical machine mechanism, and then extends the service life of the optical machine mechanism. It has a reasonable overall design and a compact structure, is easy to be installed and maintained and has strong practicability.

In order to achieve the above purpose, the following technical schemes are adopted:

An efficient heat-dissipating head-up display (HUD), comprising an outer housing, wherein a light outlet through-hole is also provided on the outer housing; a light source housing, wherein the light source housing and the outer housing are detachably connected, and an optical machine mechanism is also mounted in the light source housing, and the optical machine mechanism is used to output image light to the outer housing; a heat conducting member is also connected between the optical machine mechanism and the light source housing, and the heat conducting member is used to conduct heat generated by the optical machine mechanism to the light source housing: the light source housing is also arranged with a first heat-dissipating member, which is used to dissipate the heat conducted by the heat conducting member to the light source housing to the outside; an image adjusting mechanism, wherein the image adjusting mechanism is arranged in the outer housing, and the image adjusting mechanism is used to receive and adjust the image light output by the optical machine mechanism, and emit the image light after adjustment to an external imaging element for imaging through the light outlet through-hole; and a printed circuit board (PCB) master control component, wherein the PCB master control component is detachably mounted on the light source housing, and the PCB master control component is used to control operations of the entire HUD.

Further, the optical machine mechanism comprises a light source mounting base, an optical machine light source and a second heat-dissipating member mounted on the light source mounting base; one inner wall of the light source housing is also provided with a heat-dissipating protruding block; the heat conducting member comprises a plurality of first heat conducting sheets, and each of the first heat conducting sheets comprises a heat conduction fixing part and a heat conduction connecting part; each of the heat conduction fixing parts is fixedly connected with an outer wall of the light source mounting base, and each of the heat conduction connecting parts is inclined to extend downwards and attached to a surface of the heat-dissipating protruding block.

Further, the first heat-dissipating member comprises a plurality of first heat-dissipating fins, and the second heat-dissipating member comprises a plurality of second heat-dissipating fins mounted on the light source mounting base; the outer wall of the light source housing is also provided with a first heat-dissipating position corresponding to the heat-dissipating protruding block at one side, and the plurality of first heat-dissipating fins are arranged on the first heat-dissipating position; the first heat-dissipating position is also provided with a plurality of first screw holes, which are used to install screws to lock the heat conducting connecting parts on the heat-dissipating protruding block; one side of the light source housing is also provided with a first opening corresponding to the optical machine mechanism, and a package plate can also be detachably installed at the first opening; and, a plurality of third heat-dissipating fins are also arranged on the outer wall of the light source housing at one end near the optical machine mechanism.

Further, the image adjusting mechanism comprises an optical path adjusting component and an image adjusting component; the optical path adjusting component comprises an adjusting reflector; the adjusting reflector is arranged on the inner wall of the light source housing at one end, and the adjusting reflector is located on a light outlet optical path of the optical machine mechanism, and the adjusting reflector is used to reflect the image light outputted by the optical machine mechanism to the image adjusting component; the image adjusting component comprises an adjusting support frame, a diffusion sheet, a fixed reflector and a rotating reflector; the adjusting support frame is installed in the outer housing, and the top of the adjusting support frame is also integrated with a fixed mirror fixing frame at one end, and the bottom of the adjusting support frame is also integrated with a diffusion sheet fixing frame; the diffusion sheet and the fixed reflector are respectively installed on the diffusion sheet fixing frame and the fixed mirror fixing frame; the rotating reflector is movably arranged on the other end of the top of the adjusting support frame; a light channel is also provided inside the diffusion sheet fixing frame, and reflected light reflected by the optical path adjusting component passes through the diffusion sheet, and is incident on the fixed reflector through the light channel, and then the fixed reflector reflects the light to the rotating reflector, and finally the rotating reflector emits the light through the light outlet through-hole to the outside.

Further, the image adjusting component further comprises a rotating support frame and a rotating driving mechanism; the rotating reflector is installed on the rotating support frame; two opposite sides of the outer housing are also respectively installed with a rotating fixing member, and two ends of the rotating support frame are respectively installed with a rotating connecting member corresponding to the rotating fixing member; each rotating connecting member is connected with the rotating fixing member, and the rotating driving mechanism is used to drive the rotating support frame to rotate relative to the rotating fixing member through the rotating connecting member.

Further, a rotating damping component is also installed on each of the rotating fixing members; the rotating damping component is in contact with the rotating connecting member, and the rotating damping component is used to produce damping on the rotating support frame when the rotating support frame performs a rotating movement.

Further, the rotating connecting member comprises a rotating shaft; one end of the rotating shaft is connected with the rotating support frame, and the other end of the rotating shaft is also connected with a rotating ball head; the rotating fixing member comprises a fixing plate and a rotating shaft column arranged on one side of the fixing plate; one end of the rotating shaft column is also provided with a first through-hole, and the rotating ball head is movably inserted in the first through-hole; the other side of the fixing plate is also provided with a limit slot communicated with the first through-hole; the rotating damping component comprises a fixing sheet, a silicone gasket and a damping boss; the fixing sheet is installed in the limit slot, the damping boss is connected with one side of the fixing sheet, and the damping boss is inserted in the first through-hole; the silicone gasket comprises a first connecting part and a first rotating part; the rotating ball head is also provided with a limit hole; and the first rotating part is inserted in the limit hole, and outer walls on both sides of the first connecting part are respectively in contact with the damping boss and the rotating ball head.

Further, the rotating support frame is also mounted with a limit pendulum rod; the rotating driving mechanism is also mounted with a travel limit sensor, and one end of the limit pendulum rod is arranged near the travel limit sensor, and the travel limit sensor is used to limit a swing stroke of the limit pendulum rod; the rotating driving mechanism comprises a worm wheel, a worm screw, a rotating driving component and an elastic member, the worm wheel is installed on the rotating support frame, and the worm screw is engaged with the worm wheel; the elastic member is used to provide an elastic force to the rotating driving component so that the worm screw is closely connected with the worm wheel; and the rotating driving component is used to rotate the rotating support frame by driving the worm screw and worm wheel.

Further, the rotating driving mechanism further comprises a mounting bracket, a limit PCB board is also installed on one side of the mounting bracket, two travel limit sensors are provided, and the two travel limit sensors are arranged at an interval on the limit PCB board; the limit pendulum rod has an L-shaped structure, and a horizontal end of the L-shaped limit pendulum rod is connected with one side of the worm wheel, and a vertical end of the L-shaped limit pendulum rod extends downwards between the two travel limit sensors; the rotating driving component comprises a worm screw groove housing, a rotating shaft and a rotating motor; the worm screw groove housing is arranged in the mounting bracket, and the worm screw groove housing is also provided with a worm screw accommodating groove for placing the worm screw; the rotating shaft is installed in the worm screw, the rotating motor is arranged at one end of the worm screw groove housing, and an output shaft of the rotating motor passes through the worm screw groove housing and is connected with the rotating shaft; one side of the mounting bracket far away from the limit PCB board is also provided with a support elastic arm, and the support elastic arm is elastic; one side of the mounting bracket mounted with the limit PCB board, and the support elastic arm are also respectively provided with a motor fixing hole, and two sides of the worm screw groove housing are also respectively provided with a fixing column corresponding to the motor fixing hole; and each fixing column is correspondingly inserted into the motor fixing hole.

Further, the elastic member is an elastic sheet; the elastic sheet comprises a second connecting part and an elastic part having elasticity; the second connecting part is connected with an outer wall of one end of the worm screw groove housing, the elastic part is arranged at the bottom of the worm screw groove housing, and one end of the elastic part extends towards the other end of the worm screw groove housing; one end of the mounting bracket is also provided with a support part, and the one end of the elastic part extending towards the other end of the worm screw groove housing is arranged on the support part; and one end of the bottom of the worm screw groove housing is also provided with a support column corresponding to the support part, and the support column is arranged on the support part.

By adopting the above schemes, the beneficial effects of the present invention are as follows:

By connecting the heat conducting member between the optical machine mechanism and the light source housing, heat generated by the optical machine mechanism in the operating process can be directly conducted to the light source housing through the heat conducting member, thus improving the heat conduction efficiency. Then, the first heat-dissipating member arranged on the light source housing would directly dissipate the heat conducted by the heat conducting member to the outside, which greatly improves heat dissipation effect of the optical machine mechanism, and then extends the service life of the optical machine mechanism. It has a reasonable overall design and a compact structure, is easy to be installed and maintained and has strong practicability.

### BRIEF DESCRIPTION OF THE DRAWINGS

FIG. 1 is a stereogram of the present invention:

FIG. 2 is a stereogram of a light source housing and an optical machine mechanism of the present invention;

FIG. 3 is a stereogram of FIG. 2 omitting a PCB master control component;

FIG. 4 is a stereogram of FIG. 3 omitting a package plate;

FIG. 5 is a stereogram of the optical machine mechanism of the present invention;

FIG. 6 is a stereogram of FIG. 1 omitting an outer housing and the light source housing;

FIG. 7 is a stereogram of FIG. 6 from another perspective.

FIG. 8 is a stereogram of the outer housing and an image adjusting mechanism of the present invention;

FIG. 9 is a local magnification diagram at A of FIG. 8;

FIG. 10 is a stereogram of a rotating driving mechanism and a rotating support frame of the present invention;

FIG. 11 is a stereogram of a rotating fixing member of the present invention;

FIG. 12 is an explosion diagram of FIG. 11;

FIG. 13 is a local cross-section diagram of a connection between the rotating fixing member and a rotating connecting member of the present invention;

FIG. 14 is a stereogram of the rotating driving mechanism of the present invention; and

FIG. 15 is an explosion diagram of FIG. 14.

### DESCRIPTION OF REFERENCE NUMBERS

1—outer housing; 2—light source housing; 3—optical machine mechanism; 4—image adjusting mechanism; 5—PCB master control component; 6—rotating driving mechanism; 7—rotating fixing member; 8—rotating connecting member; 9—rotating damping component; 11—clamping bracket; 12—rotating mirror slot; 13—dust cover; 21—first opening; 22—package plate; 31—first heat-dissipating member; 32—heat conducting member; 33—second heat-dissipating member; 34—light source mounting base; 35—optical machine light source; 36—heat-dissipating protruding block; 37—first screw hole; 41—optical path adjusting component; 42—image adjusting component; 61—limit pendulum rod; 62—travel limit sensor; 63—worm wheel; 64—worm screw; 65—rotating driving component; 66—elastic member; 67—mounting bracket; 68—limit PCB board; 71—fixing plate; 72—rotating shaft column; 73—first through-hole; 74—limit slot; 81—rotating shaft; 82—rotating ball head; 83—limit hole; 91—fixing sheet; 92—silicone gasket; 93—damping boss; 321—heat conduction fixing part; 322—heat conduction connecting part; 421—adjusting support frame; 422—diffusion sheet; 423—fixed reflector; 424—rotating reflector; 425—fixed mirror fixing frame; 426—diffusion sheet fixing frame; 427—rotating support frame; 428—second opening; 631—first fixing part; 632—transmission part; 633—first positioning column; 651—worm screw groove housing; 652—rotating shaft; 653—rotating motor; 661—second connecting part; 662—elastic part; 671—support elastic arm; 672—fixing column; 673—support part; 674—support column; 675—positioning limit block; 676—motor bracket; 921—first connecting part; 922—first rotating part.

### DESCRIPTION OF THE EMBODIMENTS

The present invention is described in detail in combination with the attached drawings and specific embodiments.

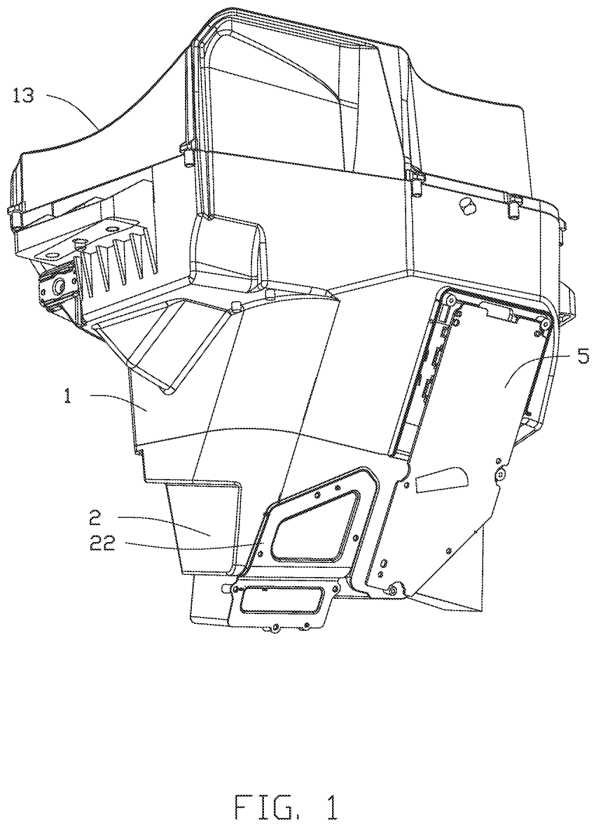

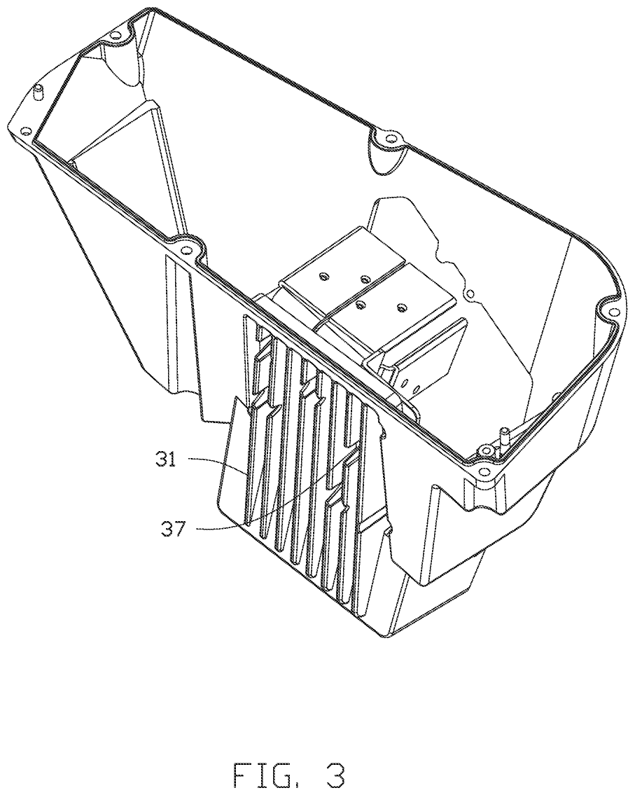

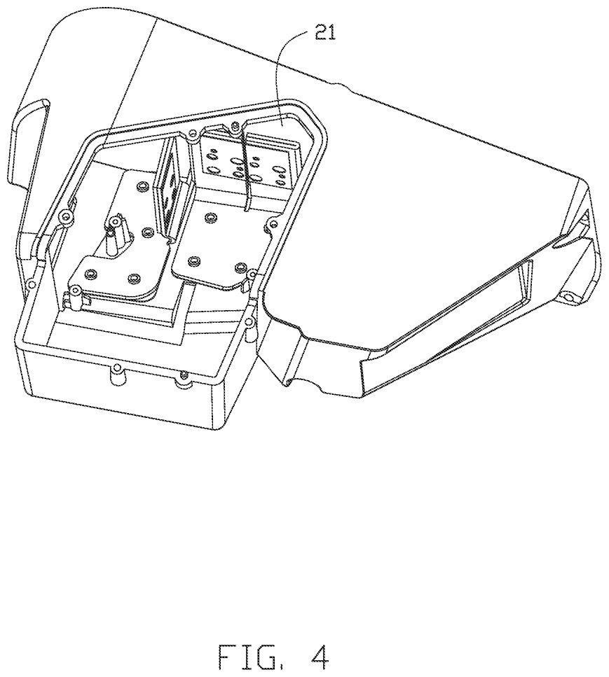

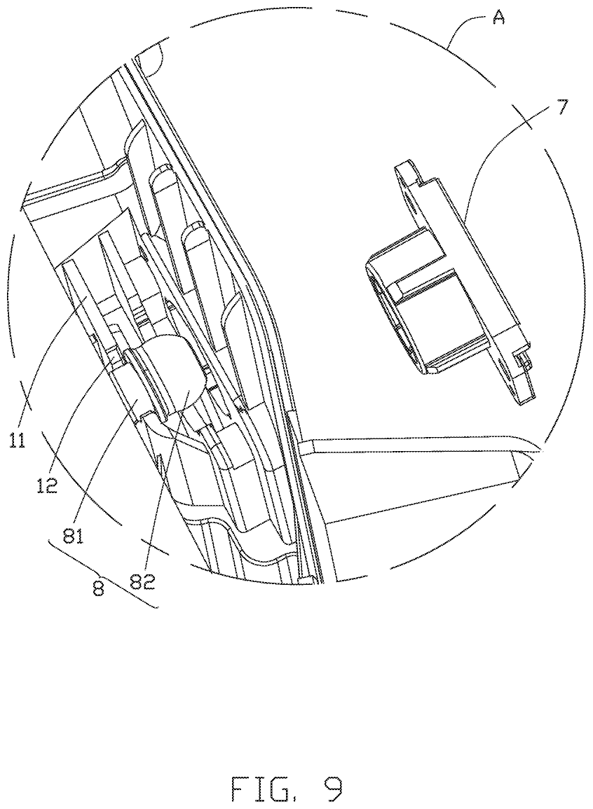

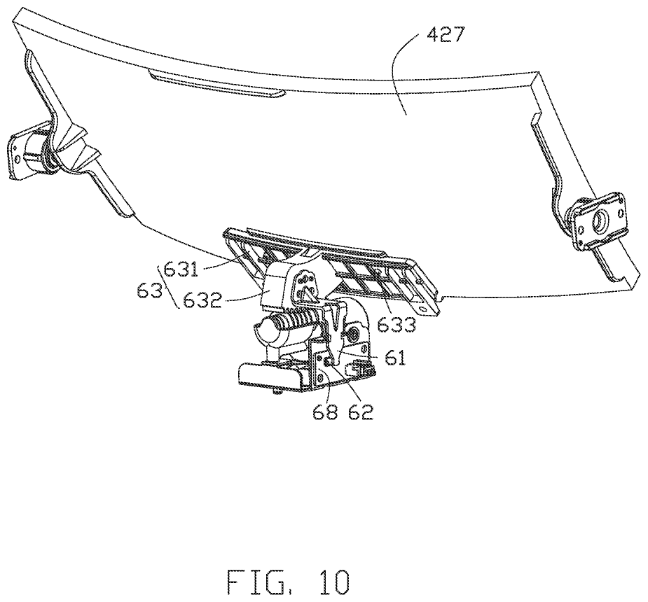

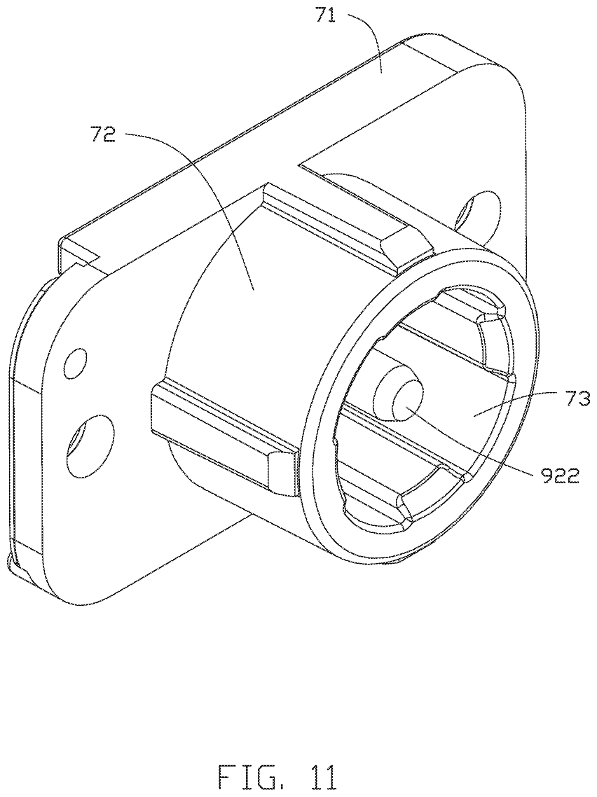

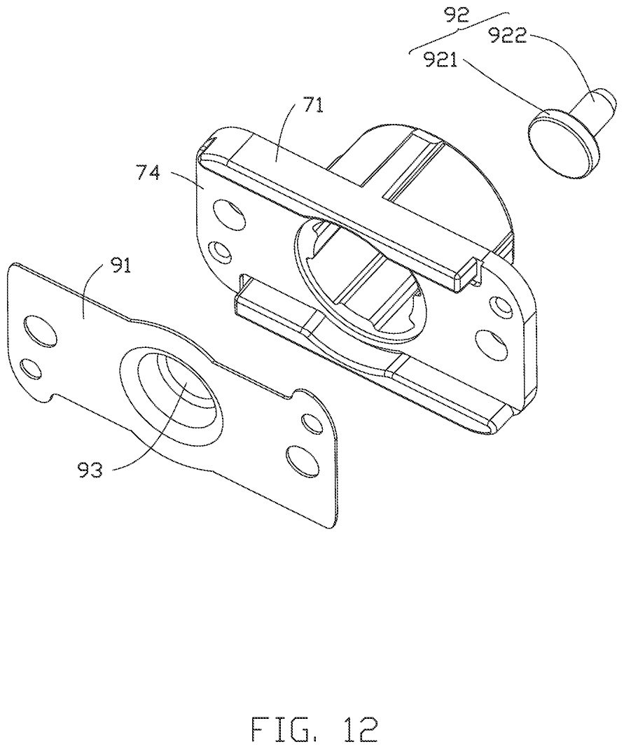

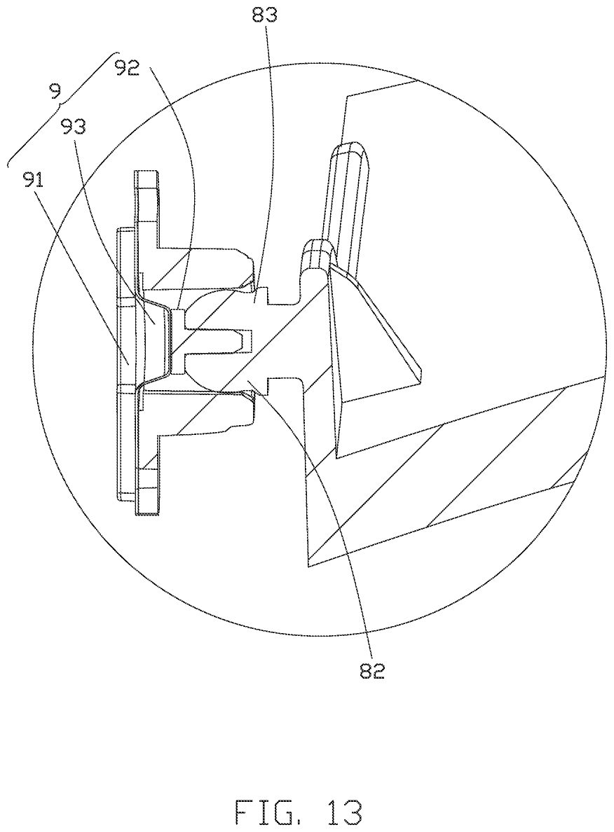

Referring to FIG. 1 to FIG. 15, the present invention provides an efficient heat-dissipating head-up display (HUD), comprising an outer housing 1, wherein a light outlet through-hole is also provided on the outer housing 1; a light source housing 2, wherein the light source housing 2 and the outer housing 1 are detachably connected, and an optical machine mechanism 3 is also mounted in the light source housing 2, and the optical machine mechanism 3 is used to output image light into the outer housing 1; a heat conducting member 32 is also connected between the optical machine mechanism 3 and the light source housing 2, and the heat conducting member 32 is used to conduct heat generated by the optical machine mechanism 3 to the light source housing 2; the light source housing 2 is also arranged with a first heat-dissipating member 31, which is used to dissipate the heat conducted by the heat conducting member 32 to the light source housing 2 to the outside; an image adjusting mechanism 4, wherein the image adjusting mechanism 4 is arranged in the outer housing 1, and the image adjusting mechanism 4 is used to receive and adjust the image light output by the optical machine mechanism 3, and emit the image light after adjustment to an external imaging element for imaging through the light outlet through-hole; and a printed circuit board (PCB) master control component 5, wherein the PCB master control component 5 is detachably mounted on the light source housing 2, and the PCB master control component 5 is used to control operations of the entire HUD.

The optical machine mechanism 3 comprises a light source mounting base 34 and an optical machine light source 35 and a second heat-dissipating member 33 mounted on the light source mounting base 34; the heat conducting member 32 is connected between the light source mounting base 34 and an inner wall of the light source housing 2, and the first heat-dissipating member 31 is arranged on an outer wall of the light source housing 2; the inner wall of the light source housing 2 is also provided with a heat-dissipating protruding block 36 at one side; the heat conducting member 32 comprises a plurality of first heat conducting sheets, and each of the first heat conducting sheets comprises a heat conduction fixing part 321 and a heat conduction connecting part 322; each heat conduction fixing part 321 is fixedly connected with an outer wall of the light source mounting base 34, and each heat conduction connecting part 322 is inclined to extend downwards and attached to a surface of the heat-dissipating protruding block 36; the first heat-dissipating member 31 comprises a plurality of first heat-dissipating fins, and the second heat-dissipating member 33 comprises a plurality of second heat-dissipating fins mounted on the light source mounting base 34; the outer wall of the light source housing 2 is also provided with a first heat-dissipating position corresponding to the heat-dissipating protruding block 36 at one side, and the plurality of first heat-dissipating fins are arranged on the first heat-dissipating position; the first heat-dissipating position is also provided with a plurality of first screw holes 37, wherein the plurality of first screw holes 37 are used to install screws to lock the heat conducting connecting parts 322 on the heat-dissipating protruding block 36; one side of the light source housing 2 is also provided with a first opening 21 corresponding to the optical machine mechanism 3, and a package plate 22 can also be detachably installed at the first opening 21; a plurality of third heat-dissipating fins are also arranged on the outer wall of the light source housing 2 at one end near the optical machine mechanism 3; the image adjusting mechanism 4 comprises an optical path adjusting component 41 and an image adjusting component 42; the optical path adjusting component 41 is used to reflect the image light emitted by the optical machine mechanism 3 to the image adjusting component 42; the image adjusting component 42 is used to adjust the received reflected light, and the adjusted reflected light is emitted to the outside through the light outlet through-hole; and the optical path adjusting component 41 comprises an adjusting reflector, wherein the adjusting reflector is arranged on the inner wall of the light source housing 2 at one end, and the adjusting reflector is located on a light outlet optical path of the optical machine mechanism 3, and the adjusting reflector is used to reflect the image light outputted by the optical machine mechanism 3 to the image adjusting component 42.

The image adjusting component 42 comprises an adjusting support frame 421, a diffusion sheet 422, a fixed reflector 423 and a rotating reflector 424. The adjusting support frame 421 is installed in the outer housing 1, and the top of the adjusting support frame 421 is also integrated with a fixed mirror fixing frame 425 at one end, and the bottom of the adjusting support frame 421 is also integrated with a diffusion sheet fixing frame 426. The diffusion sheet 422 and the fixed reflector 423 are respectively installed on the diffusion sheet fixing frame 426 and the fixed mirror fixing frame 425. The rotating reflector 424 is movably arranged on the other end of the top of the adjusting support frame 421. A light channel is also provided inside the diffusion sheet fixing frame 426, and reflected light reflected by the optical path adjusting component 41 passes through the diffusion sheet 422, and is incident on the fixed reflector 423 through the light channel, and then the fixed reflector 423 reflects the light to the rotating reflector 424, and finally the rotating reflector 424 emits the light through the light outlet through-hole to the outside. The image adjusting component 42 further comprises a rotating support frame 427 and a rotating driving mechanism 6. The rotating reflector 424 is installed on the rotating support frame 427. Two opposite sides of the outer housing 1 are also respectively installed with a rotating fixing member 7, and two ends of the rotating support frame 427 are respectively installed with a rotating connecting member 8 corresponding to the rotating fixing member 7.

Each rotating connecting member 8 is connected with the rotating fixing member 7, and the rotating driving mechanism 6 is used to drive the rotating support frame 427 to rotate relative to the rotating fixing member 7 through the rotating connecting member 8. A rotating damping component 9 is also installed on each of the rotating fixing members 7. The rotating damping component 9 is in contact with the rotating connecting member 8, and the rotating damping component 9 is used to produce damping on the rotating support frame when the rotating support frame 427 performs a rotating movement. The rotating connecting member 8 comprises a rotating shaft 81. One end of the rotating shaft 81 is connected with the rotating support frame 427, and the other end of the rotating shaft 81 is also connected with a rotating ball head 82. The rotating fixing member 7 comprises a fixing plate 71 and a rotating shaft column 72 arranged on one side of the fixing plate 71. One end of the rotating shaft column 72 is also provided with a first through-hole 73, and the rotating ball head 82 is movably inserted in the first through-hole 73. The other side of the fixing plate 71 is also provided with a limit slot 74 communicated with the first through-hole 73. The rotating damping component 9 comprises a fixing sheet 91, a silicone gasket 92 and a damping boss 93. The fixing sheet 91 is installed in the limit slot 74, the damping boss 93 is connected with one side of the fixing sheet 91, and the damping boss 93 is inserted in the first through-hole 73. The silicone gasket 92 is connected between the damping boss 93 and the rotating ball head 82. The silicone gasket 92 comprises a first connecting part 921 and a first rotating part 922. The rotating ball head 82 is also provided with a limit hole 83. The first rotating part 922 is inserted in the limit hole 83, and outer walls on both sides of the first connecting part 921 are respectively in contact with the damping boss 93 and the rotating ball head 82.

The outer housing 1 is also provided with a clamping bracket 11 near the two rotating connecting members 8, and each clamping bracket 11 is provided with a rotating mirror slot 12. A connection point of the rotating ball head 82 of each rotating connecting member 8 and the rotating shaft 81 is correspondingly clamped on the rotating mirror slot 12. A limit pendulum rod 61 is also installed on the rotating support frame 427. A travel limit sensor 62 is also installed on the rotating driving mechanism 6, and one end of the limit pendulum rod 61 is arranged near the travel limit sensor 62, wherein the travel limit sensor 62 is used to limit a swing stroke of the limit pendulum rod 61. The rotating driving mechanism 6 comprises a worm wheel 63, a worm screw 64, a rotating driving component 65 and an elastic member 66. The worm wheel 63 is installed on the rotating support frame 427, and the worm screw 64 is engaged with the worm wheel 63. The elastic member 66 is used to provide an elastic force to the rotating driving component 65 so that the worm screw 64 is closely connected with the worm wheel 63. The rotating driving component 65 is used to rotate the rotating support frame 427 by driving the worm screw 64 and worm wheel 63. The rotating driving mechanism 6 also comprises a mounting bracket 67, and the rotating driving component 65 is installed in the mounting bracket 67. A limit PCB board 68 is also installed on one side of the mounting bracket 67, and two travel limit sensors 62 are provided, and the two travel limit sensors 62 are arranged at an interval on the limit PCB board 68. The limit pendulum rod 61 has an L-shaped structure, and a horizontal end of the L-shaped limit pendulum rod 61 is connected with one side of the worm wheel 63, and a vertical end of the L-shaped limit pendulum rod 61 extends downwards between the two travel limit sensors 62. The rotating driving component 65 comprises a worm screw groove housing 651, a rotating shaft 652 and a rotating motor 653. The worm screw groove housing 651 is arranged in the mounting bracket 67, and the worm screw groove housing 651 is also provided with an accommodating groove of the worm screw 64 for placing the worm screw 64. The rotating shaft 652 is installed in the worm screw 64, the rotating motor 653 is arranged at one end of the worm screw groove housing 651, and an output shaft of the rotating motor 653 passes through the worm screw groove housing 651 and is connected with the rotating shaft 652. One side of the mounting bracket 67 far away from the limit PCB board 68 is also provided with a support elastic arm 671, and the support elastic arm 671 is elastic. One side of the mounting bracket 67 mounted with the limit PCB board 68, and the support elastic arm 671 are also respectively provided with a motor fixing hole and two sides of the worm screw groove housing 651 are also respectively provided with a fixing column 672 corresponding to the motor fixing hole. Each fixing column 672 is correspondingly inserted into the motor fixing hole.

The elastic member 66 is an elastic sheet; the elastic sheet comprises a second connecting part 661 and an elastic part 662 having elasticity; the second connecting part 661 is connected with an outer wall of one end of the worm screw groove housing 651, the elastic part 662 is arranged at the bottom of the worm screw groove housing 651, and one end of the elastic part 662 extends towards the other end of the worm screw groove housing 651; one end of the mounting bracket 67 is also provided with a support part 673, and the one end of the elastic part 662 extending towards the other end of the worm screw groove housing 651 is arranged on the support part 673; and one end of the bottom of the worm screw groove housing 651 is also provided with a support column 674 corresponding to the support part 673, and the support column 674 is arranged on the support part 673. The worm wheel 63 comprises a first fixing part 631 and a transmission part 632. The lower part of one side of the rotating support frame 427 is also provided with a plurality of first positioning columns 633, and the first fixing part 631 is arranged on the rotating support frame 427 through a plurality of the first positioning columns 633. The transmission part 632 has a fan-shaped structure, and one side wall of the transmission part 632 is connected with the first fixing part 631. A fan-shaped arc surface of the transmission part 632 is also provided with a tooth groove for meshing with the worm screw 64. The light outlet through-hole of the outer housing 1 is also provided with a dust cover 13.

A Working Principle of the Present Invention:

Continuing to refer to FIG. 1 to FIG. 15, in one embodiment, the HUD comprises an outer housing 1, a light source housing 2, an optical machine mechanism 3, an image adjusting mechanism 4, and a PCB master control component 5. The light source housing 2 and the outer housing 1 are detachably connected, the optical machine mechanism 3 is arranged in the light source housing 2, image light emitted by the optical machine mechanism 3 is directly incident into the outer housing 1, the image adjusting mechanism 4 can receive and adjust the image light, and the adjusted image light is emitted to an external imaging element for imaging through a light outlet through-hole. In this embodiment, the imaging element is a front windshield of a vehicle, and the image light forms a virtual image on the front windshield for observation of a driver, and the PCB master control component 5 is installed on an outer wall of the light source housing 2 and connected with various electric driving elements of the HUD, which can control a normal operation of the entire HUD. In this embodiment, a dust cover 13 is also provided at the light outlet through-hole of the outer housing 1, the image light adjusted by the image adjusting mechanism 4 is incident on the front windshield of the vehicle through the dust cover 13, and the dust cover 13 can avoid dust and other impurities entering the outer housing 1 to avoid affecting the normal operation of the HUD while ensuring that it is clean and tidy.

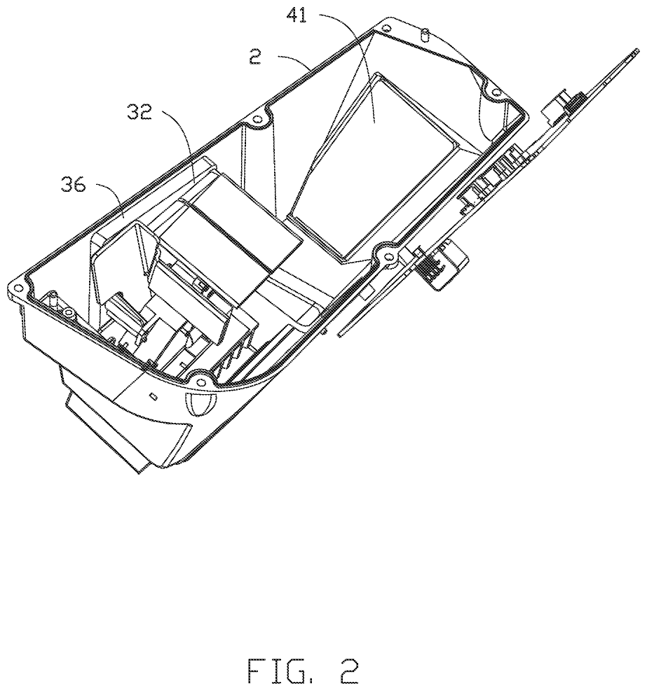

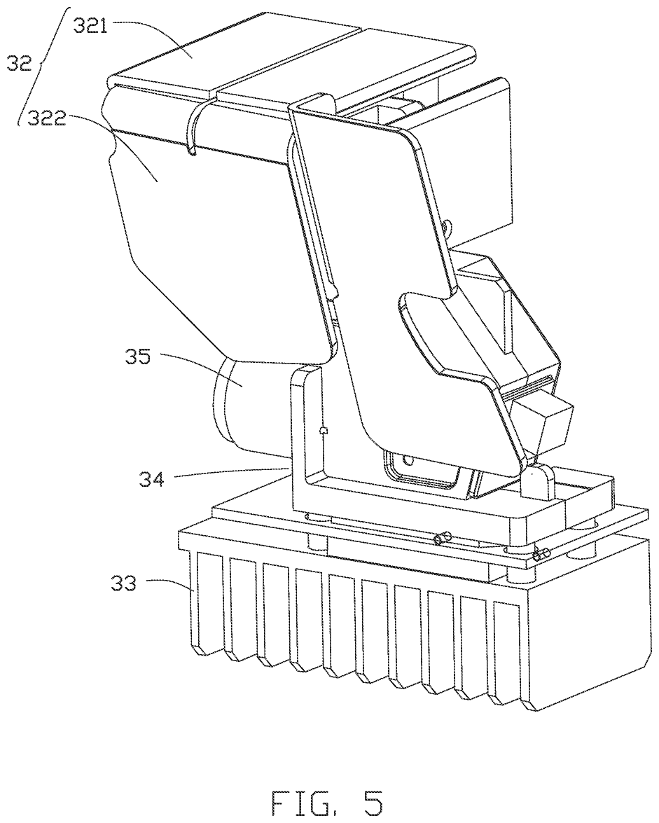

The optical machine mechanism 3; as shown in FIG. 2 to FIG. 5, in an embodiment, the optical machine mechanism 3 comprises a light source mounting base 34, and an optical machine light source 35 (an RGB three-color light source that emits the image light) mounted on the light source mounting base 34. In this embodiment, a heat conducting member 32 is connected between the light source mounting base 34 and an inner wall of the light source housing 2, heat generated by the optical machine light source 35 during a working process can be directly transmitted to the light source housing 2 through the heat conducting member 32, thereby improving heat conduction efficiency; and then, through a first heat dissipating member 31 arranged on the outer wall of the light source housing 2, the heat conducted by the heat conducting member 32 is directly dissipated to the outside, so as to further improve heat dissipation effect of the optical machine light source 35, and thus extend a service life of the optical machine light source 35. In order to further improve the heat dissipation efficiency, a second heat-dissipating element 33 (including a plurality of second heat-dissipating fins) is also mounted on the light source mounting base. In one embodiment, as shown in FIG. 5, the heat conducting member 32 comprises two first heat conducting sheets, wherein a heat conduction fixing part 321 of one of the first heat conducting sheets is fixably connected with the top of the light source mounting base 34, a heat conduction fixing part 321 of the other one of the first heat conducting sheets is fixedly connected with one end of the upper part of the light source mounting base 34. Each heat conduction connecting part 322 extends downwards and is attached to a surface of a heat-dissipating protruding block 36, which can increase a contact area thereof and improve the heat conduction efficiency.

In one embodiment, the first heat-dissipating member 31 is first heat-dissipating fins, and the first heat-dissipating fins are arranged on a first heat-dissipating position, and the first heat-dissipating position is arranged corresponding to the heat-dissipating protruding block 36, and the heat conducted to the heat-dissipating protruding block 36 can be dissipated to the outside through the first heat-dissipating fins. In one embodiment, the heat conduction connecting part 322 can be locked to the heat-dissipating protruding block 36 to ensure stability of the connection by mounting a screw in a first screw hole 37 on the first heat-dissipating position. In order to enhance the heat dissipation effect of the optical machine light source 35, in one embodiment, a plurality of third heat-dissipating fins are also arranged on the outer wall of one end of the light source housing 2 near the optical machine light source 35. In one embodiment, one side of the light source housing 2 is also provided with a first opening 21 corresponding to the optical machine light source 35; during assembly of the HUD, work such as adjusting an installation position of the light source mounting base 34 and locking the screw can be adjusted through the first opening 21; meanwhile, the optical machine light source 35 can be adjusted through the first opening 21 (such as focal length adjustment) to facilitate installation and maintenance; in addition, at the first opening 21, a package plate 22 can be detachably mounted; and after installing the optical machine, the package plate 22 can be used to seal it to ensure that it is not easy to be damaged. In one embodiment, an outer wall of one side of the light source housing 2 is also provided with a first fixing position, and the PCB master control component 5 (comprising the housing and PCB control board) can be installed on the first fixing position for convenient assembly.

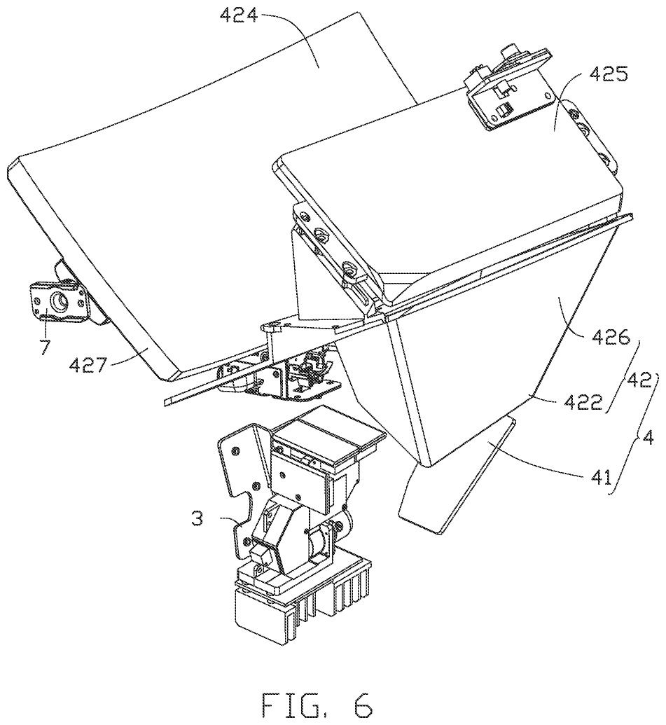

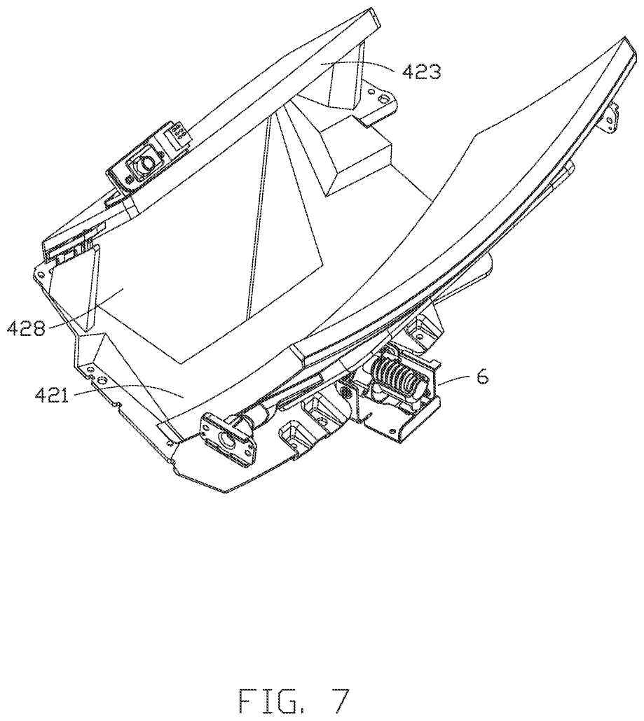

An image adjusting component 42; as shown in FIG. 6 and FIG. 7, in one embodiment, one end of the diffusion sheet fixing frame 426 is integrated with the bottom of an adjusting support frame 421, and a second opening 428 is provided at the end of the diffusion sheet fixing frame 426 at which the adjusting support frame 421 is connected. The other end of the diffusion sheet fixing frame 426 extends under the adjusting support frame 421 and is arranged in the light source housing 2, and a third opening is provided at the end of the diffusion sheet fixing frame 426 extended to the light source housing 2. Both ends of a light channel are communicated with the second opening 428 and the third opening respectively. A fixed mirror fixing frame 425 is integrated with the top end of the adjusting support frame 421, and the fixed mirror fixing frame 425 is arranged near the second opening 428. The fixed mirror fixing frame 425 is provided with a mounting port, and a fixed reflector 423 is fixed on the mounting port.

The diffusion sheet fixing frame 426 and the fixed mirror fixing frame 425 are integrated with the bottom and top of the adjusting support frame 421 respectively. The integrated connection method can reduce an installation volume of the HUD and facilitate installation and maintenance. Meanwhile, enough installation space can be left to introduce a cooling system and improve heat-dissipating efficiency of the HUD. In addition, it can also omit a number of brackets for fixing the corresponding components, thus greatly reducing production costs. In one embodiment, the light channel as a whole is horn-shaped, the third opening is an entrance of the light channel, the second opening 428 is an exit of the light channel, and an aperture of the second opening 428 is larger than that of the third opening, which can cause a light beam to form diffuse reflection. In one embodiment, the light channel is also coated with a light absorbing layer, and the light absorbing layer may be matting paint coated on the inner wall of the light channel. In one embodiment, a diffusion sheet 422 is glued and fixed on the third opening, and the diffusion sheet 422 can contain useful light to avoid scattered light. In one embodiment, the fixed mirror fixing frame 425 is also connected with two support plates, which can further improve the stability of the structure, and one side of each support plate is coated with a second light absorbing layer, the second light absorbing layer can be matting paint to avoid transmission of the light beam; image light emitted by the optical machine light source 35 is first incident on an adjusting reflector installed on the inner wall of the light source housing 2, the adjusting reflector would reflect the light to the diffusion sheet 422; and, after passing through the diffusion sheet 422, the reflected light is incident on the fixed reflector 423 through the light channel, and then the fixed reflector 423 reflects the light to a rotating reflector 424, and finally the rotating reflector 424 emits the light to the outside through the light outlet through-hole.

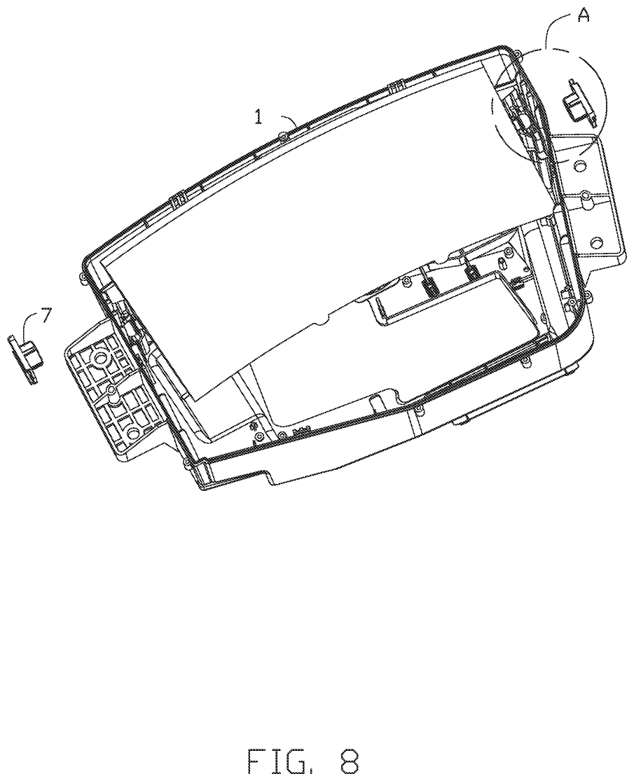

The rotating reflector 424; as shown in FIG. 8 to FIG. 13, a rotating mirror mounting hole is provided on each of the opposite sides of the outer housing 1, and a locking hole is provided on a fixing plate 71 of each rotating fixing member 7. The locking hole is used to install a screw to lock the fixing plate 71 on the outer wall of one side of the outer housing 1 provided with a rotating mirror mounting hole. Meanwhile, a rotating shaft column 72 on the fixing plate 71 passes through the rotating mirror mounting hole and is inserted into the outer housing 1 so as to be connected with rotating connecting members 8 at both ends of a rotating support frame 427 (in this embodiment, the rotating connecting members 8 are respectively installed at two ends of the rotating support frame 427 corresponding to the two rotating mirror installation holes). The combination of internal and external installation can improve the convenience of installation and the stability of the structure.

In one embodiment, one end of a rotating shaft 81 of the rotating connecting member 8 is connected with a rotating ball head 82; a connection between the rotating ball head 82 and the rotating shaft 81 is a step structure; the rotating ball head 82 is inserted in a first through-hole 73 of a rotating shaft column 72, and the rotating ball head 82 is provided with a limit hole 83: when a first rotating part 922 of a silicone gasket 92 is inserted in the limit hole 83, an end face of the rotating ball head 82 would be in contact with a first connecting part 921 of the silicone gasket 92. At this time, when the rotating mirror rotates, the rotating ball head 82 would rotate in the first through-hole 73, and due to damping (friction resistance) between the rotating ball head 82 and the silicone gasket 92, a free rotation amplitude of the rotating mirror can be limited to ensure the stability of rotation of the rotating mirror (certain damping can be generated in a process of rotating the rotating mirror, so as to ensure the stability of the rotating mirror; while improving the rotation accuracy of the rotating mirror, it can also ensure that a formed virtual image remains stable during the process of rotating the rotating mirror); in addition, the first rotating part 922 of the silicone gasket 92 is inserted in the limit hole 83, which can reduce friction loss between structural parts, and at the same time, it can also provide higher damping, which can protect the rotating structural parts, and further improve the precision and stability of rotation adjustment. In one embodiment, end faces of the rotating ball head 82 in contact with the first connecting part 921 are flat, which can further increase the damping. In one embodiment, two clamping brackets 11 are also provided in the outer housing 1, each clamping bracket 11 is arranged near a rotating connecting member 8, and each clamping bracket 11 is provided with a rotating mirror slot 12; the step structure of the connection between the rotating ball head 82 of each rotating connecting member 8 and the rotating shaft 81 is clamped on the rotating mirror slot 12 (the rotating ball head 82 can be rotated on the rotating mirror slot 12 to limit its position), which can ensure the rotating stability of the rotating mirror support frame. In one embodiment, a fixed connecting hole is also provided at each end of the rotating support frame 427, and one end of the rotating shaft 81 of the rotating connecting member 8 can be inserted in the fixed connecting hole when the rotating connecting members 8 are installed.

In one embodiment, the rotating fixing member 7 and a rotating damping component 9 are both made of metallic materials, such as stainless steel. In this embodiment, a plurality of hot melt columns are also provided in the limit slot 74 on one side of the fixing plate 71, and the fixing sheet 91 is inserted in the limit slot 74 when the fixing sheet 91 is installed; a first positioning hole (the fixing sheet 91 is provided with the first positioning hole) is sleeved on the hot melt columns, the hot melt columns pass through the first positioning hole, and the ends of the hot melt columns are hot fused by a high temperature, and then the fixing sheet 91 is fixed on the fixing plate 71. In another embodiment, the rotating fixing member 7 and the rotating damping component 9 are made of non-metallic materials, such as plastic. In this embodiment, the limit slot 74 on one side of the fixing plate 71 is provided with a number of positioning screw holes; when installing the fixing sheet 91, the fixed sheet 91 is inserted into the limit slot 74; the first fixing holes are aligned with the positioning screw holes (the positioning screw holes are provided on the fixing sheet 91), and the fixing sheet 91 can be locked on the fixing plate 71 by screws; the thickness of the fixing sheet 91 is not limited, and can be adjusted according to the weight of the rotating mirror; when the weight of the rotating mirror is large, the fixed sheet 91 of larger thickness can be selected; when the weight of the rotating mirror is small, the fixing sheet 91 of smaller thickness can be selected; after the fixing sheet 91 is installed, a damping boss 93 located on one side of the fixing sheet 91 is inserted into the first through-hole 73 for easy and convenient operation.

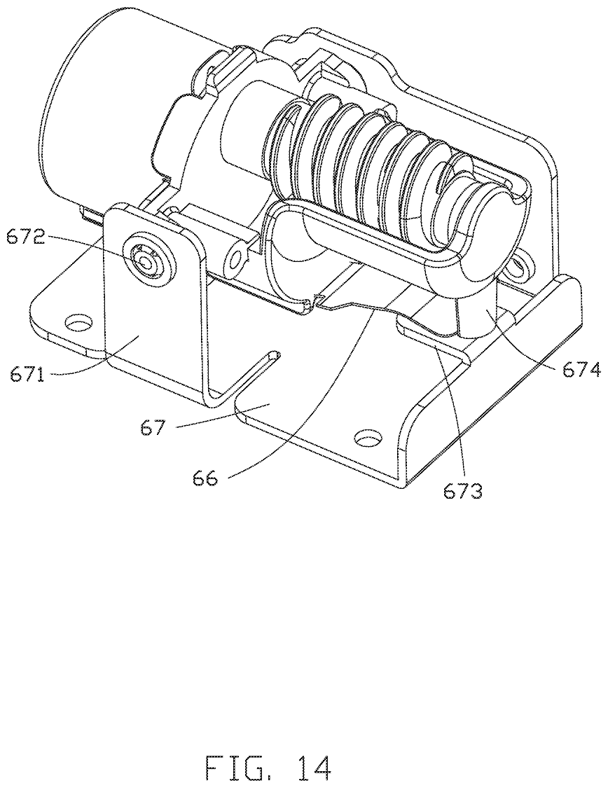

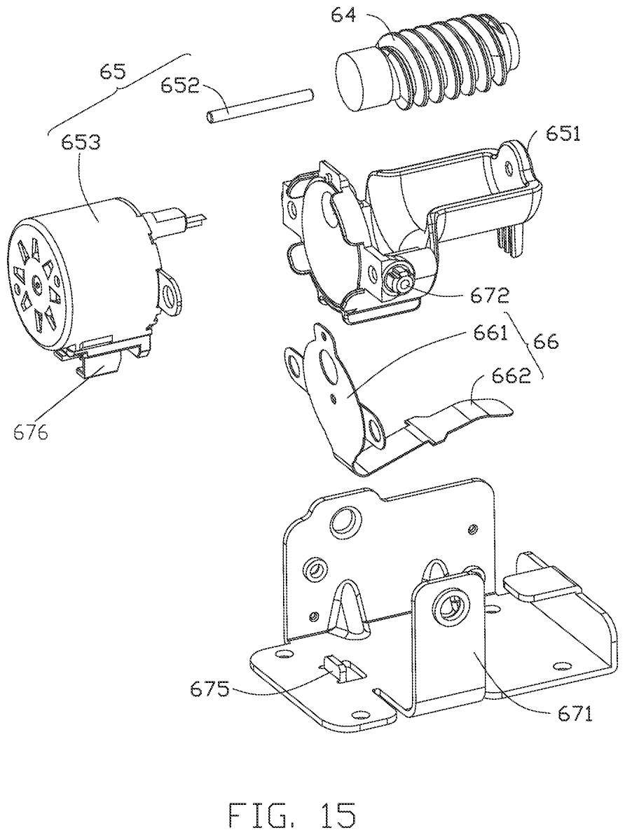

A rotating driving mechanism 6: As shown in FIG. 14 and FIG. 15, in one embodiment, a positioning limit block 675 is also provided at one end of a mounting bracket 67 away from a support part 673, and a motor bracket 676 is also provided at the bottom of a rotating motor 653 corresponding to the positioning limit block 675, a slot is also provided on the motor bracket 676, and the positioning limit block 675 is inserted in the slot; the bottom of the mounting bracket 67 is also provided with a plurality of support positioning columns, and the mounting bracket 67 is also provided with a plurality of positioning screw holes (which can be easily installed in the light source housing 2). In one embodiment, a limit pendulum rod 61 is also installed on the rotating support frame 427, one end of the limit pendulum rod 61 extends downwards, and a travel limit sensor 62 is also installed on the rotating driving mechanism 6, and a swing stroke of the limit pendulum rod 61 can be limited through the travel limit sensor 62, thereby limiting a rotation angle of the rotating reflector 424.

Continue to refer to FIG. 14 and FIG. 15, a worm wheel 63 is installed on a lower part of the back of the rotating support frame 427, the rotating driving mechanism 6 is arranged under the worm wheel 63, and a worm screw 64 of the rotating driving mechanism 6 is meshed with the worm wheel 63, and the worm screw 64 rotates under driving of a rotating driving component 65, thus driving the rotating support frame 427 to rotate through the worm wheel 63 (in one embodiment, the worm wheel 63 comprises a first fixing part 631 and a transmission part 632, and the first fixing part 631 is fixed on the rotating support frame 427 (a lower part of one side of the rotating support frame 427 is also provided with a plurality of first positioning columns 633, which can be used to position it; and the first fixing part 631 can be attached to it by double-sided tape or liquid glue), the transmission part 632 is a fan-shaped structure, and one side wall of the transmission part 632 is connected with the first fixing part 631, the transmission part 632 is provided with a tooth groove on a protruding arc surface, and the worm screw 64 is meshed with the tooth groove), so as to adjust an angle of the rotating support frame 427. In this embodiment, a transmission method employing the worm wheel 63 and the worm screw 64 is used to drive the rotating support frame 427 to rotate, which can ensure the smoothness of rotation of the rotating support frame 427 to a certain extent and reduce noise; meanwhile, there is also a travel limit sensor 62, which can limit the rotation angle of the rotating support frame 427 to ensure the safety of its rotation. In addition, an elastic member 66 can provide an elastic force to the rotating driving component 65, so that the worm screw 64 and the worm wheel 63 are closely connected, and a rotation delay of the rotating support frame 427 caused by an excessive tooth gap is solved. Meanwhile, it also solves the problem of clamping caused by interference fit between the worm screw 64 and the worm wheel 63, and makes a fit tolerance range of the worm screw 64 and the worm wheel 63 larger, which is conducive to production and processing of the worm wheel 63 and the worm screw 64, and then reduces the processing cost.

In one embodiment, two travel limit sensors 62 are provided, the two travel limit sensors 62 are arranged at an interval, the limit pendulum rod 61 has an L-shaped structure, and a horizontal end of the L-shaped limit pendulum rod 61 is connected with one side of the worm wheel 63, and a vertical end of the L-shaped limit pendulum rod 61 extends downwards between the two travel limit sensors 62, and by setting the two travel limit sensors 62, an initial position before swing and an extreme position after the swing of the limit pendulum rod 61 can be restricted. When assembling the rotating driving component 65, a rotating shaft 652 can be first inserted into the worm screw 64, then the worm screw 64 is inputted into an accommodating groove of the worm screw 64, then a rotating motor 653 is installed by screws at one end of a worm screw groove housing 651, and an output shaft of the rotating motor 653 passes through the worm screw groove housing 651 and is connected to the rotating shaft 652. Finally, the worm screw groove housing 651 can be buckled into the mounting bracket 67, and the assembly is convenient and quick.

In one embodiment, the mounting bracket 67 is also provided with a support elastic arm 671, and the mounting bracket 67 is mounted on one side of a limit PCB board 68, and a motor fixing hole is correspondingly provided on the support elastic arm 671. The support elastic arm 671 has certain elasticity, and when the worm screw groove housing 651 is buckled into the mounting bracket 67, the support elastic arm 671 would be extruded outwards. The support elastic arm 671 is slightly deformed, so that a distance between it and one side of the mounting bracket 67 at which the limit PCB board 68 is installed is increased, and it is convenient to place the worm screw groove housing 651. Then, the support elastic arm 671 recovers, and the worm screw groove housing 651 can be limited under the driving of a recovery force. Meanwhile, in this embodiment, the two sides of the worm screw groove housing 651 are also provided with two fixing columns 672 corresponding to the two motor fixing holes. When the worm screw groove housing 651 is clamped, each fixing column 672 is correspondingly inserted into a motor fixing hole, and a screw can be used to lock in the motor fixing hole to avoid the rotating motor 653 falling off.

In one embodiment, the elastic member 66 is an elastic sheet, and when assembling the elastic sheet, a connecting part of the elastic sheet can be installed at one end of the worm screw groove housing 651 by a screw (the end of which the rotating motor 653 is installed, the elastic sheet is installed first, and then the rotating motor 653 is installed, and the output shaft of the rotating motor 653 passes successively through the connecting part and the worm screw groove housing 651). The elastic part 662 is arranged on the bottom of the worm screw groove housing 651, and one end of the elastic part 662 is placed on the support part 673 of the mounting bracket 67; and the elastic part 662 can provide an upward elastic force on the worm screw groove housing 651 to make the worm wheel 63 and worm screw 64 connected tightly. In one embodiment, a positioning limit block 675 is also provided in the mounting bracket 67, and the positioning limit block 675 is inserted into a slot on the motor bracket 676 to limit the rotating motor 653. Meanwhile, a support column 674 at one end of the bottom of the worm screw groove housing 651 is arranged on the support part 673 to support and limit the worm screw groove housing 651.

The above are only preferred embodiments of the present invention and are not intended to limit the present invention. Any modification, equivalent replacement, improvement. etc. made within the spirit and principles of the present invention shall be included in the protection scope of the present invention.

What is claimed is:

1. An efficient heat-dissipating head-up display (HUD), comprising:
an outer housing, on which a light outlet through-hole is provided;
a light source housing, wherein the light source housing and the outer housing are detachably connected, and an optical machine mechanism is also mounted in the light source housing, and the optical machine mechanism is used to output image light to the outer housing; a heat conducting member is also connected between the optical machine mechanism and the light source housing, and the heat conducting member is used to conduct heat generated by the optical machine mechanism to the light source housing; the light source housing is also arranged with a first heat-dissipating member, which is used to dissipate the heat conducted by the heat conducting member to the light source housing to the outside;
an image adjusting mechanism, wherein the image adjusting mechanism is arranged in the outer housing, and the image adjusting mechanism is used to receive and adjust the image light output by the optical machine mechanism, and emit the image light after adjustment to an external imaging member for imaging through the light outlet through-hole; and
a printed circuit board (PCB) master control component, wherein the PCB master control component is detachably mounted on the light source housing, and the PCB master control component is used to control operation of the entire HUD.

2. The efficient heat-dissipating HUD according to claim 1, wherein the optical machine mechanism comprises a light source mounting base, an optical machine light source and a second heat-dissipating member mounted on the light source mounting base; one inner wall of the light source housing is also provided with a heat-dissipating protruding block: the heat conducting member comprises a plurality of first heat conducting sheets, and each of the first heat conducting sheets comprises a heat conduction fixing part and a heat conduction connecting part; each of the heat conduction fixing parts is fixedly connected with an outer wall of the light source mounting base, and each of the heat conduction connecting parts is inclined to extend downwards and attached to a surface of the heat-dissipating protruding block.

3. The heat-dissipating HUD according to claim 2, wherein the first heat-dissipating member comprises a plurality of first heat-dissipating fins, and the second heat-dissipating member comprises a plurality of second heat-dissipating fins mounted on the light source mounting base; the outer wall of the light source housing is also provided with a first heat-dissipating position corresponding to the heat-dissipating protruding block at one side, and the plurality of first heat-dissipating fins are arranged on the first heat-dissipating position; the first heat-dissipating position is also provided with a plurality of first screw holes, which are used to install screws to lock the heat conducting connecting parts on the heat-dissipating protruding block; one side of the light source housing is also provided with a first opening corresponding to the optical machine mechanism, and a package plate can also be detachably installed at the first opening; and, a plurality of third heat-dissipating fins are also arranged on the outer wall of the light source housing at one end near the optical machine mechanism.

4. The efficient heat-dissipating HUD according to claim 1, wherein the image adjusting mechanism comprises an optical path adjusting component and an image adjusting component; the optical path adjusting component comprises an adjusting reflector; the adjusting reflector is arranged on the inner wall of the light source housing at one end, and the adjusting reflector is located on a light outlet optical path of the optical machine mechanism, and the adjusting reflector is used to reflect the image light output by the optical machine mechanism to the image adjusting component; the image adjusting component comprises an adjusting support frame, a diffusion sheet, a fixed reflector and a rotating reflector; the adjusting support frame is installed in the outer housing, and the top of the adjusting support frame is also integrated with a fixed mirror fixing frame at one end, and the bottom of the adjusting support frame is also integrated with a diffusion sheet fixing frame; the diffusion sheet and the fixed reflector are respectively installed on the diffusion sheet fixing frame and the fixed mirror fixing frame; the rotating reflector is movably arranged on the other end of the top of the adjusting support frame; a light channel is also provided inside the diffusion sheet fixing frame, and reflected light reflected by the optical path adjusting component passes through the diffusion sheet, and is incident on the fixed reflector through the light channel, and then the fixed reflector reflects the light to the rotating reflector, and finally the rotating reflector emits the light through the light outlet through-hole to the outside.

5. The efficient heat-dissipating HUD according to claim 4, wherein the image adjusting component further comprises a rotating support frame and a rotating driving mechanism; the rotating reflector is installed on the rotating support frame; two opposite sides of the outer housing are also respectively installed with a rotating fixing member, and two ends of the rotating support frame are respectively installed with a rotating connecting member corresponding to the rotating fixing member; each rotating connecting member is connected with the rotating fixing member, and the rotating driving mechanism is used to drive the rotating support frame to rotate relative to the rotating fixing member through the rotating connecting member.

6. The efficient heat-dissipating HUD according to claim 5, wherein a rotating damping component is also installed on each of the rotating fixing members; the rotating damping component is in contact with the rotating connecting member, and the rotating damping component is used to produce damping on the rotating support frame when the rotating support frame performs a rotating movement.

7. The efficient heat-dissipating HUD according to claim 6, wherein the rotating connecting member comprises a rotating shaft; one end of the rotating shaft is connected with the rotating support frame, and the other end of the rotating shaft is also connected with a rotating ball head; the rotating fixing member comprises a fixing plate and a rotating shaft column arranged on one side of the fixing plate; one end of the rotating shaft column is also provided with a first through-hole, and the rotating ball head is movably inserted in the first through-hole; the other side of the fixing plate is also provided with a limit slot communicated with the first through-hole; the rotating damping component comprises a fixing sheet, a silicone gasket and a damping boss; the fixing sheet is installed in the limit slot, the damping boss is connected with one side of the fixing sheet, and the damping boss is inserted in the first through-hole; the silicone gasket comprises a first connecting part and a first rotating part; the rotating ball head is also provided with a limit hole; and the first rotating part is inserted in the limit hole, and outer walls on both sides of the first connecting part are respectively in contact with the damping boss and the rotating ball head.

8. The efficient heat-dissipating HUD according to claim 5, wherein the rotating support frame is also mounted with a limit pendulum rod; the rotating driving mechanism is also mounted with a travel limit sensor, and one end of the limit pendulum rod is arranged near the travel limit sensor, and the travel limit sensor is used to limit a swing stroke of the limit pendulum rod; the rotating driving mechanism comprises a worm wheel, a worm screw, a rotating driving component and an elastic member; the worm wheel is installed on the rotating support frame, and the worm screw is engaged with the worm wheel; the elastic member is used to provide an elastic force to the rotating driving component so that the worm screw is closely connected with the worm wheel; and the rotating driving component is used to rotate the rotating support frame by driving the worm screw and worm wheel.

9. The efficient heat-dissipating HUD according to claim 8, wherein the rotating driving mechanism further comprises a mounting bracket, a limit PCB board is also installed on one side of the mounting bracket, two travel limit sensors are provided, and the two travel limit sensors are arranged at an interval on the limit PCB board; the limit pendulum rod has an L-shaped structure, and a horizontal end of the L-shaped limit pendulum rod is connected with one side of the worm wheel, and a vertical end of the L-shaped limit pendulum rod extends downwards between the two travel limit sensors; the rotating driving component comprises a worm screw groove housing, a rotating shaft and a rotating motor; the worm screw groove housing is arranged in the mounting bracket, and the worm screw groove housing is also provided with a worm screw accommodating groove for placing the worm screw; the rotating shaft is installed in the worm screw, the rotating motor is arranged at one end of the worm screw groove housing, and an output shaft of the rotating motor passes through the worm screw groove housing and is connected with the rotating shaft; one side of the mounting bracket far away from the limit PCB board is also provided with a support elastic arm, and the support elastic arm is elastic; one side of the mounting bracket mounted with the limit PCB board, and the support elastic arm are also respectively provided with a motor fixing hole, and two sides of the worm screw groove housing are also respectively provided with a fixing column corresponding to the motor fixing hole; and each fixing column is correspondingly inserted into the motor fixing hole.

10. The efficient heat-dissipating HUD according to claim 9, wherein the elastic member is an elastic sheet; the elastic sheet comprises a second connecting part and an elastic part having elasticity; the second connecting part is connected with an outer wall of one end of the worm screw groove housing, the elastic part is arranged at the bottom of the worm screw groove housing, and one end of the elastic part extends towards the other end of the worm screw groove housing; one end of the mounting bracket is also provided with a support part, and the one end of the elastic part extending towards the other end of the worm screw groove housing is arranged on the support part; and one end of the bottom of the worm screw groove housing is also provided with a support column corresponding to the support part, and the support column is arranged on the support part.
